(19) United States
(12) Patent Application Publication
(10) Pub. No.: US 2026/0060032 A1
(43) Pub. Date: Feb. 26, 2026

(54) BONDING APPARATUS, BONDING SYSTEM, AND BONDING METHOD

(71) Applicant: Tokyo Electron Limited, Tokyo (JP)

(72) Inventor: Toru SUGIYAMA, Yokohama (JP)

(73) Assignee: Tokyo Electron Limited, Tokyo (JP)

(21) Appl. No.: 19/303,941

(22) Filed: Aug. 19, 2025

(30) Foreign Application Priority Data
Aug. 20, 2024 (JP) 2024-138474

(51) Int. Cl. H01L 21/68; H01L 21/67; H01L 23/544

(52) U.S. Cl. CPC H01L 21/681; H01L 21/67121; H01L 23/544; H01L 2223/54426

(57) ABSTRACT

A bonding apparatus includes a first holder, a second holder, a mover, an optical system, an adjusting device and control circuitry. The first holder holds a first substrate. The second holder holds a second substrate. The mover brings a first one of the first holder and the second holder closer to a second one of the first holder and the second holder. The optical system images alignment marks provided on the first substrate and the second substrate. The adjusting device adjusts a depth of focus of the optical system. The control circuitry performs an approach processing and an imaging processing. In the approach processing, the control circuitry brings the first one closer to the second one. In the imaging processing, the control circuitry images, during the approach processing, the alignment marks, after locating the first substrate and the second substrate within the depth of focus of the optical system.

### CROSS-REFERENCE TO RELATED APPLICATION

This application claims the benefit of Japanese Patent Application No. 2024-138474 filed on Aug. 20, 2024, the entire disclosures of which are incorporated herein by reference.

### TECHNICAL FIELD

The various aspects and embodiments described herein pertain generally to a bonding apparatus, a bonding system, and a bonding method.

### BACKGROUND

Conventionally, there is known a bonding apparatus that bonds substrates, such as semiconductor wafers, together (see, for example, Patent Document 1).
Patent Document 1: International Publication No. 2018/088094

### SUMMARY

In an exemplary embodiment, a bonding apparatus includes a first holder, a second holder, a moving device, an optical system, an adjusting device and a controller. The first holder is configured to hold a first substrate. The second holder is configured to hold a second substrate to be bonded to the first substrate. The moving device is configured to bring a first one of the first holder and the second holder closer to a second one of the first holder and the second holder. The optical system is configured to radiate light to the first substrate held by the first holder and the second substrate held by the second holder to image alignment marks provided on the first substrate and the second substrate by reflected light or transmitted light. The adjusting device is provided on an optical path of the optical system, and configured to adjust a depth of focus of the optical system. The controller is configured to perform an approach processing and an imaging processing. In the approach processing, the controller controls the moving device to bring the first one of the first holder and the second holder closer to the second one of the first holder and the second holder. In the imaging processing, the controller images, during the approach processing, the alignment marks of the first substrate and the second substrate by the optical system, after locating the first substrate and the second substrate within the depth of focus of the optical system by controlling the adjusting device to adjust the depth of focus of the optical system.

### BRIEF DESCRIPTION OF THE DRAWINGS

FIG. 1 is a schematic plan view illustrating a configuration of a bonding system according to an exemplary embodiment;

FIG. 2 is a schematic side view of an upper wafer and a lower wafer according to the exemplary embodiment;

FIG. 3 is a schematic plan view illustrating a configuration of a bonding apparatus according to the exemplary embodiment;

FIG. 4 is a schematic side view illustrating the configuration of the bonding apparatus according to the exemplary embodiment;

FIG. 5 is a schematic diagram illustrating an upper chuck and a lower chuck according to the exemplary embodiment;

FIG. 6 is a diagram illustrating a configuration of an alignment mark imaging device according to the exemplary embodiment;

FIG. 7 is a diagram illustrating an example of an alignment mark provided on the upper wafer;

FIG. 8 is a diagram illustrating an example of an alignment mark provided on the lower wafer;

FIG. 9 is a diagram illustrating an example arrangement of the alignment mark and the alignment mark imaging device;

FIG. 10 is a flowchart illustrating a sequence of a processing performed by the bonding system according to the exemplary embodiment;

FIG. 11 is a flowchart illustrating an example of a specific sequence of a position alignment processing in a process S110;

FIG. 12 is a diagram illustrating an operation example in an imaging processing;

FIG. 13 is a diagram illustrating an operation example in the imaging processing;

FIG. 14 is a diagram illustrating a configuration example of an alignment mark imaging device according to a first modification example of the exemplary embodiment; and

FIG. 15 is a diagram illustrating a configuration example of an alignment mark imaging device according to a second modification example of the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, embodiments for a bonding apparatus, a bonding system, and a bonding method according to the present disclosure (hereinafter, referred to as “exemplary embodiments”) will be described in detail with reference to the accompanying drawings. Further, it should be noted that the present disclosure is not limited by the exemplary embodiments. Furthermore, unless processing contents are contradictory, the various exemplary embodiments can be appropriately combined. In addition, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some errors and tolerances in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “θ direction.”

### Exemplary Embodiment

### Configuration of Bonding System

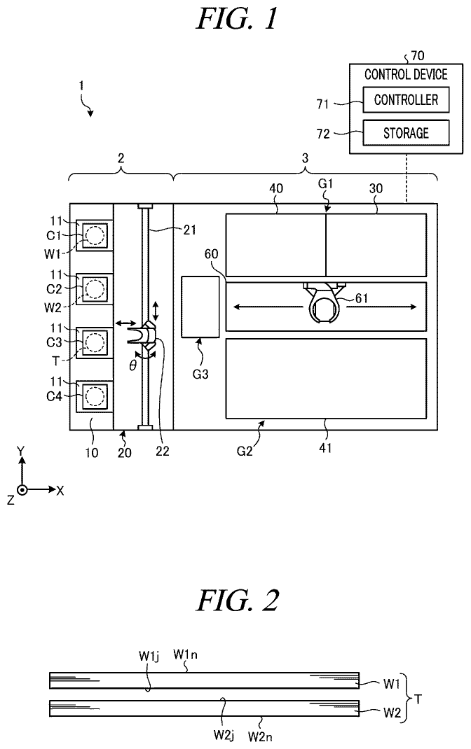

First, a configuration of a bonding system 1 according to an exemplary embodiment will be explained with reference to FIG. 1 and FIG. 2. FIG. 1 is a schematic plan view illustrating the configuration of the bonding system 1 according to the exemplary embodiment. FIG. 2 is a schematic side view of an upper wafer W1 and a lower wafer W2 according to the exemplary embodiment.

The bonding system 1 shown in FIG. 1 is configured to bond a first substrate W1 and a second substrate W2 to form a combined wafer T.

The first substrate W1 and the second substrate W2 are semiconductor substrates, such as, but not limited to, silicon wafers or compound semiconductor wafers. The first substrate W1 and the second substrate W2 have approximately the same diameter. Each of the first substrate W1 and the second substrate W2 has a circular plate shape with a diameter of, e.g., 300 mm.

Hereinafter, the First substrate W1 will be referred to as “upper wafer W1,” and the second substrate W2 will be referred to as “lower wafer W2.” That is, the upper wafer W1 is an example of a first substrate, and the lower wafer W2 is an example of a second substrate. Further, the upper wafer W1 and lower wafer W2 will sometimes be collectively referred to as “wafer W.”

In addition, hereinafter, as illustrated in FIG. 2, among plate surfaces of the upper wafer W1, the plate surface to be bonded to the lower wafer W2 will be referred to as “bonding surface W1j,” and the plate surface opposite to the bonding surface W1j will be referred to as “non-bonding surface W1n. ” Likewise, among plate surfaces of the lower wafer W2, the plate surface to be bonded to the upper wafer W1 will be referred to as “bonding surface W2j,” and the plate surface opposite to the bonding surface W2j will be referred to as “non-bonding surface W2n.”

As depicted in FIG. 1, the bonding system 1 is equipped with a carry-in/out station 2 and a processing station 3. The carry-in/out station 2 and the processing station 3 are arranged in this order along the positive X-axis direction. Also, the carry-in/out station 2 and the processing station 3 are connected as one body.

The carry-in/out station 2 includes a placement table 10 and a transfer section 20. The placement table 10 is equipped with a multiple number of placement plates 11. Provided on the placement plates 11 are cassettes C1, C2 and C3 each of which accommodates therein a plurality of (e.g., 25 sheets of) substrates horizontally. For example, the cassette C1 accommodates therein upper wafers W1; the cassette C2, lower wafers W2; and the cassettes C3, combined wafers T.

The transfer section 20 is provided adjacent to the positive X-axis side of the placement table 10. This transfer section 20 is provided with a transfer path 21 extending in the Y-axis direction, and a transfer device 22 configured to be movable along this transfer path 21.

The transfer device 22 is configured to be movable in the X-axis direction as well as in the Y-axis direction and pivotable around the Z-axis. The transfer device 22 serves to transfer the upper wafers W1, the lower wafers W2, and the combined wafers T between the cassettes C1 to C3 placed on the placement plates 11 and a third processing block G3 of the processing station 3 to be described later.

Further, the number of the cassettes C1 to C3 disposed on the placement plates 11 is not limited to the shown example. Moreover, in addition to the cassettes C1, C2, and C3, a cassette for collecting a defective substrate may be disposed on the placement plate 11.

The processing station 3 has a plurality of processing blocks equipped with various types of devices, for example, three processing blocks G1, G2 and G3. For example, the first processing block G1 is provided on the rear side (positive Y-axis side of FIG. 1) of the processing station 3, and the second processing block G2 is provided on the front side (negative Y-axis side of FIG. 1) of the processing station 3. Further, the third processing block G3 is provided on the carry-in/out station 2 side (negative X-axis side of FIG. 1) of the processing station 3.

The first processing block G1 is equipped with a surface modifying apparatus 30 configured to modify the bonding surface W1j of the upper wafer W1 and the bonding surface W2j of the lower wafer W2. The surface modifying apparatus 30 cuts a SiO₂ bond in the bonding surfaces W1j and W2j of the upper and lower wafers W1 and W2 to form a single bond of SiO, thus modifying the bonding surfaces W1j and W2j so that they can be easily hydrophilized afterwards.

Further, a surface hydrophilizing apparatus 40 is disposed in the first processing block G1. The surface hydrophilizing apparatus 40 is configured to hydrophilize the bonding surfaces W1j and W2j of the upper and lower wafers W1 and W2 with, for example, pure water, and also serves to clean the bonding surfaces W1j and W2j.

In the surface hydrophilizing apparatus 40, while rotating the upper wafer W1 or the lower wafer W2 held by, for example, a spin chuck, the pure water is supplied onto the upper wafer W1 or the lower wafer W2. Accordingly, the pure water supplied onto the upper wafer W1 or the lower wafer W2 is diffused on the bonding surface W1j of the upper wafer W1 or the bonding surface W2j of the lower wafer W2, so that the bonding surfaces W1j and W2j are hydrophilized.

In the present exemplary embodiment, the surface modifying apparatus 30 and the surface hydrophilizing apparatus 40 are arranged horizontally. However, the surface hydrophilizing apparatus 40 may be stacked on or under the surface modifying apparatus 30.

The second processing block G2 includes a bonding apparatus 41. The bonding apparatus 41 is configured to bond the hydrophilized upper and lower wafers W1 and W2 by an intermolecular force. Details of this bonding apparatus 41 will be described later.

The third processing block G3 is equipped with a transition (TRS) device (not shown) for the upper wafer W1, the lower wafer W2, and the combined wafer T. In addition, the third processing block G3 may also be equipped with a placement section in which the upper wafer W1 or the lower wafer W2 is temporarily placed. The placement section may be capable of placing multiple wafers (upper wafers W1 or lower wafers W2) therein.

Further, as depicted in FIG. 1, a transfer section 60 is formed in an area surrounded by the first processing block G1, the second processing block G2, and the third processing block G3. A transfer device 61 is disposed in the transfer section 60. The transfer device 61 has a transfer arm configured to be movable in a vertical direction and a horizontal direction and pivotable around a vertical axis, for example.

This transfer device 61 is moved within the transfer section 60 to transfer the upper wafer W1, the lower wafer W2, and the combined wafer T to devices within the first processing block G1, the second processing block G2, and the third processing block G3 adjacent to the transfer section 60.

Further, the bonding system 1 is equipped with a control device 70. The control device 70 is configured to control an operation of the bonding system 1. The control device 70 controls the operation of the bonding system 1 based on signals from switches, various sensors, and the like.

The control device 70 is, for example, a computer, and includes a controller 71 and a storage 72. The controller 71 includes a microcomputer having a central processing unit (CPU), a read only memory (ROM), a random access memory (RAM), input/output ports, etc., and various types of circuits. The CPU of the microcomputer reads and executes a program stored in the ROM, thus implementing a control to be described later. The storage 72 is implemented by, for example, a semiconductor memory device such as a RAM or a flash memory, or a storage device such as a hard disk or an optical disk. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

Such a program may have been recorded on a computer-readable recording medium and may be installed from that recording medium into the storage 72 of the control device 70. The computer-readable recording medium may be, by way of non-limiting example, a hard disk (HD), a flexible disk (FD), a compact disk (CD), a magnetic optical disk (MO), a memory card, or the like.

### Configuration of Bonding Apparatus

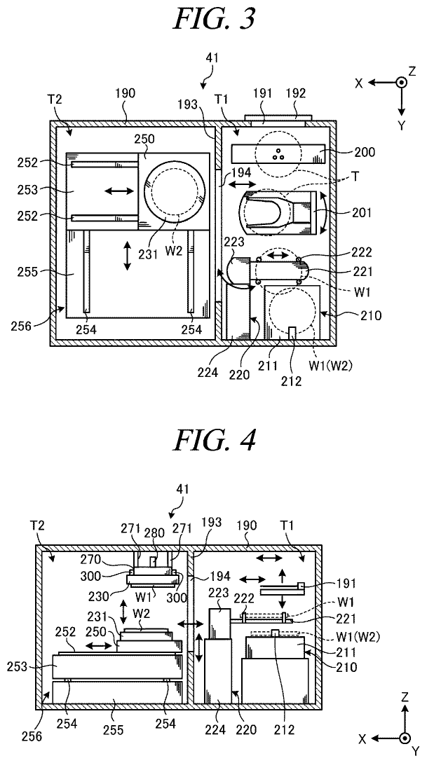

Now, a configuration of the bonding apparatus 41 will be explained with reference to FIG. 3 and FIG. 4. FIG. 3 is a schematic plan view illustrating the configuration of the bonding apparatus 41 according to the exemplary embodiment, and FIG. 4 is a schematic side view illustrating the configuration of the bonding apparatus 41 according to the exemplary embodiment.

As depicted in FIG. 3, the bonding apparatus 41 is equipped with a processing vessel 190 having a hermetically sealable inside. A carry-in/out opening 191 for the upper wafer W1, the lower wafer W2, and the combined wafer T is formed in a side surface of the processing vessel 190 on the side of the transfer section 60, and an opening/closing shutter 192 is provided at this carry-in/out opening 191.

The inside of the processing vessel 190 is partitioned into a transfer section T1 and a processing section T2 by an inner wall 193. The carry-in/out opening 191 described above is formed in the side surface of the processing vessel 190 in the transfer section T1. Further, the inner wall 193 is also provided with a carry-in/out opening 194 for the upper wafer W1, the lower wafer W2, and the combined wafer T.

In the transfer section T1, a transition device 200, a substrate transfer mechanism 201, an inverting mechanism 220, and a position adjusting mechanism 210 are arranged in this order from the carry-in/out opening 191 side, for example.

The transition device 200 temporarily places therein the upper wafer W1, the lower wafer W2, and the combined wafer T. The transition device 200 is formed in, for example, two levels, and is thus capable of placing therein any two of the upper wafer W1, the lower wafer W2, and the combined wafer T at the same time.

The substrate transfer mechanism 201 has a transfer arm configured to be movable in a vertical direction (Z-axis direction) and horizontal directions (X-axis direction and Y-axis direction) and pivotable around a vertical axis (θ direction), for example. The substrate transfer mechanism 201 is capable of transferring the upper wafer W1, the lower wafer W2, and the combined wafer T within the transfer section T1 or between the transfer section T1 and the processing section T2.

The position adjusting mechanism 210 is configured to adjust the direction of the upper wafer W1 and the lower wafer W2 in a horizontal direction. Specifically, the position adjusting mechanism 210 includes a base 211 equipped with a non-illustrated holder configured to hold and rotate the upper and lower wafers W1 and W2, and a detector 212 configured to detect the positions of notches of the upper wafer W1 and the lower wafer W2. By detecting the positions of the notches of the upper wafer W1 and the lower wafer W2 through the use of the detector 212 while rotating the upper wafer W1 and the lower wafer W2 held by the base 211, the position adjusting mechanism 210 adjusts the positions of the notches. Accordingly, the direction of the upper wafer W1 and the lower wafer W2 in the horizontal direction is adjusted.

The inverting mechanism 220 is configured to invert front and rear surfaces of the upper wafer W1. Specifically, the inverting mechanism 220 has a holding arm 221 configured to hold the upper wafer W1. The holding arm 221 extends in a horizontal direction (X-axis direction). Further, the holding arm 221 is provided with holding members 222 for holding the upper wafer W1 at, for example, four positions thereon.

The holding arm 221 is supported by a driver 223 equipped with, for example, a motor. The holding arm 221 is rotatable around a horizontal axis by this driver 223. Further, the holding arm 221 is also rotatable about the driver 223 and movable in a horizontal direction (X-axis direction). Below the driver 223, another driver provided with, for example, a motor is provided. The driver 223 can be moved in a vertical direction by this other driver along a supporting column 224 that extends in the vertical direction.

In this way, the upper wafer W1 held by the holding members 222 can be rotated around the horizontal axis by the driver 223, and can also be moved in the vertical and horizontal directions. Further, the upper wafer W1 held by the holding members 222 can be moved between the position adjusting mechanism 210 and an upper chuck 230 to be described later by being rotated about the driver 223.

Provided in the processing section T2 are the upper chuck 230 configured to attract and hold a top surface (non-bonding surface W1n) of the upper wafer W1 from above and a lower chuck 231 configured to attract and hold a bottom surface (non-bonding surface W2n) of the lower wafer W2 from below. The lower chuck 231 is disposed below the upper chuck 230, and is configured to face the upper chuck 230. The upper chuck 230 and the lower chuck 231 are, for example, vacuum chucks. The upper chuck 230 is an example of a first holder configured to hold the upper wafer W1, and the lower chuck 231 is an example of a second holder configured to hold the lower wafer W2.

As depicted in FIG. 4, the upper chuck 230 is supported by a supporting member 270 provided above the upper chuck 230. The supporting member 270 is fixed to a ceiling surface of the processing vessel 190 with, for example, a plurality of supporting columns 271 therebetween.

An alignment mark imaging device 300, which is an optical system that images a bottom surface (bonding surface W1j) of the upper wafer W1 held by the upper chuck 230 and a top surface (bonding surface W2j) of the lower wafer W2 held by the lower chuck 231, is disposed above the upper chuck 230. Specifically, the alignment mark imaging device 300 is configured to image alignment marks provided on the upper wafer W1 and the lower wafer W2.

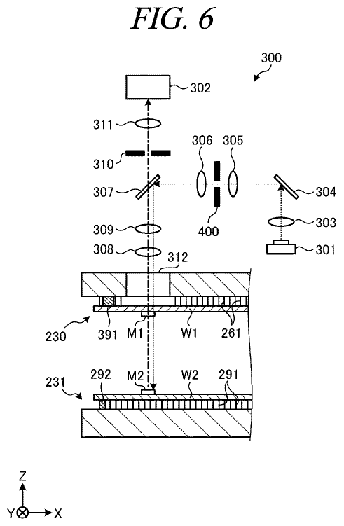

The alignment mark imaging device 300 is equipped with a light source 301 (see FIG. 6) and an imager 302 (see FIG. 6) provided above the upper chuck 230. The light source 301 is disposed above the upper chuck 230, and radiates light to the upper wafer W1 and the lower wafer W2 through a through hole 312 (see FIG. 6) formed in the upper chuck 230. The light radiated from the light source 301 is infrared light. The imager 302 is positioned above the upper chuck 230, and images the alignment marks provided on the upper wafer W1 and the lower wafer W2 through the through hole 312 formed in the upper chuck 230. The imager 302 is, by way of example, a charge coupled device (CCD) camera, and includes an infrared imaging device having a sensitivity region in an infrared band. An imaging result by the imager 302 is output to the control device 70. A more specific configuration of the alignment mark imaging device 300 will be described later with reference to FIG. 6, etc.

The lower chuck 231 is supported by a first mover 250 disposed below the lower chuck 231. The first mover 250 serves to move the lower chuck 231 in a horizontal direction (X-axis direction) as will be described later. Further, the first mover 250 is configured to be able to move the lower chuck 231 in a vertical direction and to rotate the lower chuck 231 around a vertical axis.

The first mover 250 is mounted to a pair of rails 252. The rails 252 are disposed at a bottom surface side of the first mover 250, and is elongated in a horizontal direction (X-axis direction). The first mover 250 is configured to be movable along the rails 252.

The pair of rails 252 are mounted to a second mover 253. The second mover 253 is mounted to a pair of rails 254. The rails 254 are provided on a bottom surface side of the second mover 253, and is elongated in a horizontal direction (Y-axis direction). The second mover 253 is configured to be movable in the horizontal direction (Y-axis direction) along the rails 254. Further, the pair of rails 254 are disposed on a placement table 255 which is provided on a bottom surface of the processing vessel 190.

The first mover 250, the second mover 253, and the like constitute a moving device 256. The moving device 256 moves the lower chuck 231 in the X-axis direction, the Y-axis direction, and the θ direction, thus adjusting a horizontal position of the lower chuck 231 with respect to the upper chuck 230. Here, the horizontal position refers to the position and direction in the horizontal direction (the X-axis direction, the Y-axis direction, and the θ direction).

In addition, the moving device 256 moves the lower chuck 231 in the Z-axis direction as well, thus adjusting positions of the upper wafer W1 held by the upper chuck 230 and the lower wafer W2 held by the lower chuck 231 in the vertical direction. That is, the moving device 256 adjusts the positions of the upper wafer W1 and the lower wafer W2 in the vertical direction by bringing the lower chuck 231 closer to the upper chuck 230.

Although the lower chuck 231 is moved in the X-axis direction, the Y-axis direction, and the θ direction in the present exemplary embodiment, the moving device 256 may move the lower chuck 231 in the X-axis direction and the Y-axis direction and move the upper chuck 230 in the θ direction, for example. Further, although the lower chuck 231 is moved in the Z-axis direction in the present exemplary embodiment, the moving device 256 may move the upper chuck 230 in the Z-axis direction, for example.

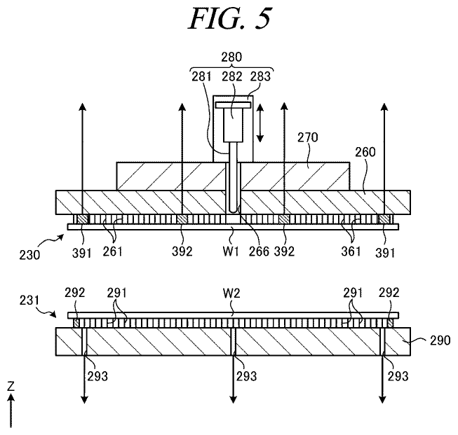

Now, configurations of the upper chuck 230 and the lower chuck 231 will be described with reference to FIG. 5. FIG. 5 is a schematic diagram illustrating the upper chuck 230 and the lower chuck 231 according to the exemplary embodiment.

As shown in FIG. 5, the upper chuck 230 has a main body 260. The main body 260 is supported by the supporting member 270. A through hole 266 is formed through the supporting member 270 and the main body 260 in a vertical direction. The position of the through hole 266 corresponds to the center of the upper wafer W1 attracted to and held by the upper chuck 230. A pressing pin 281 of a striker 280 is inserted through the through hole 266.

The striker 280 is disposed on a top surface of the supporting member 270, and is equipped with the pressing pin 281, an actuator 282, and a linearly moving mechanism 283. The pressing pin 281 is a cylindrical member extending in the vertical direction, and is supported by the actuator 282.

The actuator 282 is configured to generate a constant pressure in a certain direction (here, a vertically downward direction) by air supplied from, for example, an electro-pneumatic regulator (not shown). By the air supplied from the electro-pneumatic regulator, the actuator 282 comes into contact with a central portion of the upper wafer W1 and is capable of controlling a pressing load applied to the central portion of the upper wafer W1. Further, a leading end of the pressing pin 281 is movable up and down in the vertical direction through the through hole 266 by the air from the electro-pneumatic regulator.

The actuator 282 is supported by the linearly moving mechanism 283. The linearly moving mechanism 283 is configured to move the actuator 282 along the vertical direction by a driver having, for example, a motor embedded therein.

The striker 280 is configured as described above, and controls the movement of the actuator 282 by the linearly moving mechanism 283 and controls the pressing load on the upper wafer W1 from the pressing pin 281 by the actuator 282. Through these operations, the striker 280 presses the central portion of the upper wafer W1 held by the upper chuck 230 into contact with the lower wafer W2.

A plurality of pins 261 to be brought into contact with the top surface (non-bonding surface W1n) of the upper wafer W1 is provided on a bottom surface of the main body 260. Each of these pins 261 has a diameter of, e.g., 0.1 mm to 1 mm and a height of several tens of μm to several hundreds of μm. The plurality of pins 261 are evenly arranged at a distance of, e.g., 2 mm.

The upper chuck 230 is provided with a multiple number of attraction portions for attracting the upper wafer W1 in some of the regions where the plurality of pins 261 are provided. Specifically, a plurality of outer attraction portions 391 and a plurality of inner attraction portions 392 are provided in the bottom surface of the main body 260 of the upper chuck 230 to attract and hold the upper wafer W1 by suctioning. The plurality of outer attraction portions 391 and the plurality of inner attraction portions 392 have arc-shaped or circular ring-shaped attraction regions when viewed from the top. The outer attraction portions 391 and the inner attraction portions 392 have the same height as the pins 261.

The plurality of outer attraction portions 391 are arranged at an outer periphery of the main body 260. These outer attraction portions 391 are connected to a non-illustrated suction device such as a vacuum pump, and attract and hold an outer periphery of the upper wafer W1 by suctioning.

The plurality of inner attraction portions 392 are arranged at a radially inner side of the main body 260 than the outer attraction portions 391 along a circumferential direction. The inner attraction portions 392 are connected to a non-illustrated suction device such as a vacuum pump, and attract and hold a region between the outer periphery and the central portion of the upper wafer W1 by suctioning.

The lower chuck 231 has a main body 290 having a diameter equal to or larger than the diameter of the lower wafer W2. Here, the lower chuck 231 is illustrated as having a larger diameter than the lower wafer W2. A top surface of the main body 290 is a facing surface that faces the bottom surface (non-bonding surface W2n) of the lower wafer W2.

A plurality of pins 291 configured to be brought into contact with the bottom surface (non-bonding surface W2n) of the lower wafer W2 is provided on the top surface of the main body 290. The pins 291 have a diameter of, e.g., 0.1 mm to 1 mm and a height of several tens of μm to several hundreds of μm. The plurality of pins 291 are evenly arranged at a distance of, e.g., 2 mm.

Further, on the top surface of the main body 290, a lower rib 292 is annularly provided outside the plurality of pins 291. The lower rib 292 is formed in an annular shape near an outer edge of the lower wafer W2, and supports the outer periphery of the lower wafer W2 along the entire circumference thereof.

The main body 290 has a plurality of lower suction ports 293. The plurality of lower suction ports 293 are provided in an attraction region surrounded by the lower rib 292. These lower suction ports 293 are connected to a non-illustrated suction device such as a vacuum pump via a non-illustrated suction line.

The lower chuck 231 decompresses the attraction region surrounded by the lower rib 292 by evacuating the attraction region through the plurality of lower suction ports 293. As a result, the lower wafer W2 placed in the attraction region is attracted to and held by the lower chuck 231.

Since the lower rib 292 supports the outer periphery of the bottom surface of the lower wafer W2 along the entire circumference thereof, the lower wafer W2 is properly suctioned including the outer edge thereof. In this way, the entire surface of the lower wafer W2 can be attracted and held. In addition, since the bottom surface of the lower wafer W2 is supported by the plurality of pins 291, the lower wafer W2 can be easily separated from the lower chuck 231 when the suctioning of the lower wafer W2 is released.

### Configuration of Alignment Mark Imaging Device

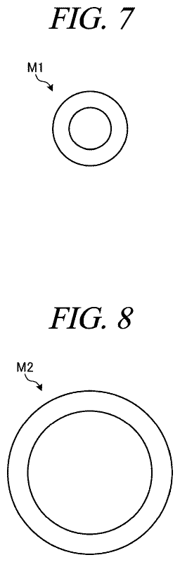

Now, a configuration of the alignment mark imaging device 300 will be explained in more detail with reference to FIG. 6 to FIG. 9. FIG. 6 is a diagram illustrating the configuration of the alignment mark imaging device 300 according to the exemplary embodiment. FIG. 7 is a diagram showing an example of an alignment mark M1 provided on the upper wafer W1, and FIG. 8 is a diagram showing an example of an alignment mark M2 provided on the lower wafer W2.

As depicted in FIG. 6, the alignment marks M1 and M2 are formed on the upper wafer W1 and the lower wafer W2 in advance, respectively. The alignment mark M1 has a ring shape, as shown in FIG. 7, for example. The alignment mark M2 has a ring shape with a diameter larger than that of the alignment mark M1, as shown in FIG. 8, for example. In a horizontal position adjustment processing to be described later, the horizontal position of the lower chuck 231 is adjusted by using the moving device 256 to align a center position of the ring shape of the alignment mark M1 with a center position of the ring shape of the alignment mark M2.

The alignment mark imaging device 300 includes the light source 301, collimator lenses 303 and 306, a reflecting mirror 304, a condensing lens 305, a half mirror 307, an objective lens 308, a relay lens 309, an imaging aperture 310, an imaging lens 311, and the imager 302.

The light source 301 emits infrared light. The collimator lens 303 collimates the light emitted from the light source 301. The reflecting mirror 304 changes the path of the light incident vertically upwards from the collimator lens 303 into a horizontal direction, directing the light to the condensing lens 305. The condensing lens 305 condenses the light incident from the reflecting mirror 304 and make it reach the collimator lens 306. The collimator lens 306 collimates the light incident from the condensing lens 305, directing the light to the half mirror 307. The half mirror 307 serves to reflect the light incident from the collimator lens 306 toward the through hole 312 side, and also serves to transmit the light incident from the through hole 312 side.

The objective lens 308 condenses the light incident from the half mirror 307 via the relay lens 309 toward the through hole 312. Also, the objective lens 308 condenses the light incident from the through hole 312 so that the light is incident on the relay lens 309. The relay lens 309 passes the light incident from the objective lens 308 through the half mirror 307 to the imaging lens 311. The imaging aperture 310 is disposed between the half mirror 307 and the imaging lens 311, and adjusts the amount of the light that is sent from the half mirror 307 to the imaging lens 311. The imaging lens 311 focuses the light incident from the half mirror 307 toward the imager 302.

With this configuration, the light source 301 of the alignment mark imaging device 300 emits the light above the upper chuck 230. As shown by dashed-line arrows in FIG. 6, the light emitted from the light source 301 reaches the upper wafer W1 and the lower wafer W2 via the collimator lens 303, the reflecting mirror 304, the condensing lens 305, the collimator lens 306, the half mirror 307, the relay lens 309, the objective lens 308, and the through hole 312. Then, as indicated by dashed-dotted-line arrows in FIG. 6, the light reflected from the upper wafer W1 and the lower wafer W2 reaches the imager 302 via the through hole 312, the objective lens 308, the relay lens 309, the half mirror 307, the imaging aperture 310, and the imaging lens 311. That is, the imager 302 images the alignment marks M1 and M2 by the reflected light through the through hole 312.

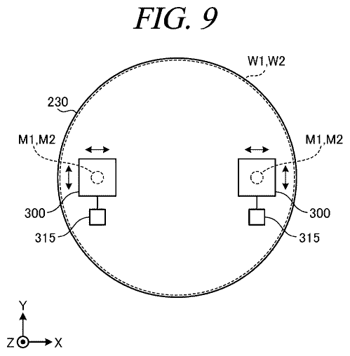

There is provided a plurality of the alignment marks M1 (M2), and these alignment marks M1 (M2) are disposed at multiple positions on the upper wafer W1 (lower wafer W2) in one-to-one correspondence with a plurality of the alignment mark imaging devices 300. By way of example, the alignment marks M1 (M2) are provided at at least two positions on one end portion and the other end portion of the upper wafer W1 (lower wafer W2), as illustrated in FIG. 9. FIG. 9 is a diagram showing an example of the arrangement of the alignment marks M1 and M2 and the alignment mark imaging devices 300. The bonding apparatus 41 is equipped with the plurality of (here, two) alignment mark imaging devices 300 to correspond to the plurality of alignment marks M1 (M2) provided on the upper wafer W1 (lower wafer W2). For example, the alignment mark imaging device 300 is provided at each of one end side and the other end side of the upper wafer W1 (lower wafer W2). The plurality of alignment mark imaging devices 300 respectively image the plurality of alignment marks M1 (M2).

The alignment mark imaging device 300 may be configured to be movable in a horizontal direction according to the positions of the alignment marks M1 (M2) provided on the upper wafer W1 (lower wafer W2). For example, the alignment mark imaging device 300 may be connected to a moving mechanism 315 and configured to be movable in the horizontal direction (the X-axis direction and the Y-axis direction) by the moving mechanism 315. The moving mechanism 315 may be, by way of non-limiting example, a rail and a stage that can be moved on the rail.

Referring back to FIG. 6, explanation of the alignment mark imaging device 300 will be carried on. An adjuster 400 configured to adjust the depth of focus of the alignment mark imaging device 300 is provided on the optical path of the alignment mark imaging device 300. The adjuster 400 is provided between the condensing lens 305 and the collimator lens 306. The adjuster 400 is a diaphragm having an aperture, and adjusts a numerical aperture (NA) of the alignment mark imaging device 300 by adjusting the width of the aperture. The adjuster 400 adjusts the depth of focus of the alignment mark imaging device 300 by varying the numerical aperture of the alignment mark imaging device 300. By way of example, the adjuster 400 can reduce the depth of focus of the alignment mark imaging device 300 by increasing the numerical aperture.

### Specific Operation of Bonding System

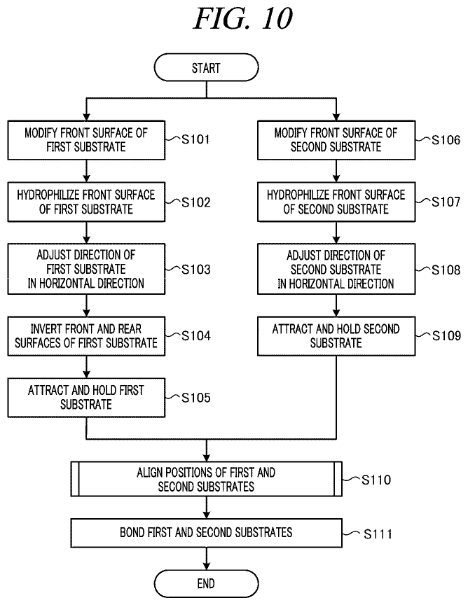

Now, a specific operation of the bonding system 1 according to the exemplary embodiment will be explained with reference to FIG. 10. FIG. 10 is a flowchart showing a sequence of a processing performed by the bonding system 1 according to the exemplary embodiment. Various processes shown in FIG. 10 are performed under the control of the control device 70.

First, the cassette C1 accommodating therein a plurality of upper wafers W1, the cassette C2 accommodating therein a plurality of lower wafers W2, and the empty cassette C3 are placed on the preset placement plates 11 of the carry-in/out station 2. Then, the upper wafer W1 is taken out of the cassette C1 by the transfer device 22, and transferred to the transition device disposed in the third processing block G3.

Next, the upper wafer W1 is transferred to the surface modifying apparatus 30 of the first processing block G1 by the transfer device 61. In the surface modifying apparatus 30, an oxygen gas as a processing gas is excited into plasma under a preset decompressed atmosphere to be ionized. The oxygen ions are radiated to the bonding surface of the upper wafer W1, so that the bonding surface is plasma-processed. As a result, the bonding surface of the upper wafer W1 is modified (process S101).

Subsequently, the upper wafer W1 is transferred to the surface hydrophilizing apparatus 40 of the first processing block G1 by the transfer device 61. In the surface hydrophilizing apparatus 40, while rotating the upper wafer W1 held by the spin chuck, pure water is supplied onto the upper wafer W1. As a result, the bonding surface of the upper wafer W1 is hydrophilized. Further, the bonding surface of the upper wafer W1 is also cleaned by the pure water (process S102).

Next, the upper wafer W1 is transferred to the bonding apparatus 41 of the second processing block G2 by the transfer device 61. The upper wafer W1 carried into the bonding apparatus 41 is transferred to the position adjusting mechanism 210 via the transition device 200, and the direction of the upper wafer W1 in the horizontal direction is adjusted by the position adjusting mechanism 210 (process S103).

Thereafter, the upper wafer W1 is delivered from the position adjusting mechanism 210 to the inverting mechanism 220, and the front and rear surfaces of the upper wafer W1 are inverted by the inverting mechanism 220 (process S104). To be specific, the bonding surface W1j of the upper wafer W1 is turned to face downwards. Subsequently, the upper wafer W1 is transferred from the inverting mechanism 220 to the upper chuck 230, and the upper wafer W1 is attracted to and held by the upper chuck 230 (process S105).

In parallel with the processes S101 to S105 upon the upper wafer W1, the lower wafer W2 is also processed. First, the lower wafer W2 is taken out of the cassette C2 by the transfer device 22, and transferred to the transition device disposed in the third processing block G3.

Next, the lower wafer W2 is transferred to the surface modifying apparatus 30 by the transfer device 61, and the bonding surface W2j of the lower wafer W2 is modified (process S106). Thereafter, the lower wafer W2 is transferred to the surface hydrophilizing apparatus 40 by the transfer device 61, and the bonding surface W2j of the lower wafer W2 is hydrophilized and cleaned (process S107).

Afterwards, the lower wafer W2 is transferred to the bonding apparatus 41 by the transfer device 61. The lower wafer W2 carried into the bonding apparatus 41 is transferred to the position adjusting mechanism 210 via the transition device 200. Then, the direction of the lower wafer W2 in the horizontal direction is adjusted by the position adjusting mechanism 210 (process S108).

Thereafter, the lower wafer W2 is transferred to the lower chuck 231, and is attracted to and held by the lower chuck 231 with the notch thereof directed toward a preset direction (process S109).

Subsequently, position alignment of the upper wafer W1 held by the upper chuck 230 and the lower wafer W2 held by the lower chuck 231 in the horizontal and vertical directions is carried out (process S110). Details of this process S110 will be elaborated later.

At the end of the position alignment processing, the distance between the bonding surface W2j of the lower wafer W2 and the bonding surface W1j of the upper wafer W1 is set to a preset distance of, e.g., 80 μm to 100 μm.

Then, a bonding processing of bonding the upper wafer W1 and the lower wafer W2 is performed (process S111). Specifically, the center of the upper wafer W1 is pressed downwards from above by using the pressing pin 281 of the striker 280 to be brought into contact with the center of the lower wafer W2, whereby the upper wafer W1 and the lower wafer W2 are bonded to each other.

Thereafter, the pressing pin 281 is raised up to the upper chuck 230. Further, vacuum evacuation of the lower wafer W2 in the lower chuck 231 is stopped, whereby the attracting/holding of the lower wafer W2 by the lower chuck 231 is released. In this way, the bonding processing in the bonding apparatus 41 is completed.

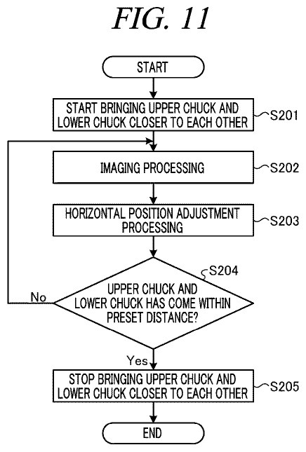

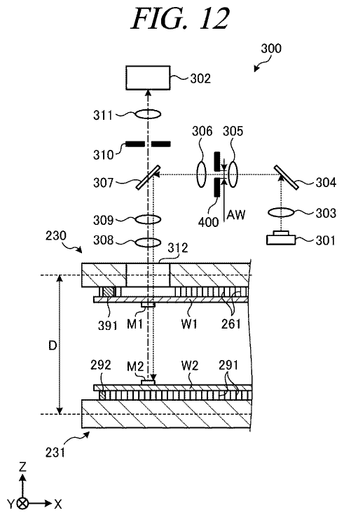

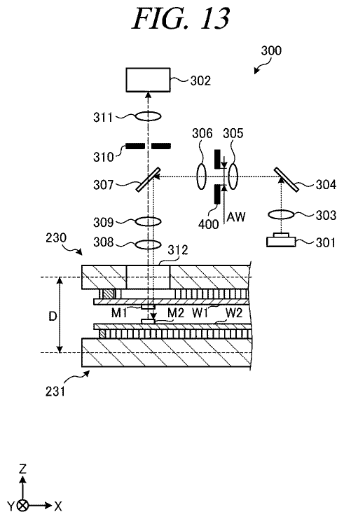

Now, an example of a specific sequence of the position alignment processing between the upper wafer W1 and the lower wafer W2 in the process S110 will be explained with reference to FIG. 11. FIG. 11 is a flowchart showing an example of a specific sequence of the position alignment processing in the process S110. FIG. 12 and FIG. 13 are diagrams illustrating an operation example in an imaging processing.

As illustrated in FIG. 11, the control device 70 starts an approach processing of bringing the upper chuck 230 and the lower chuck 231 closer to each other (process S201). In the approach processing, first, the control device 70 starts raising the lower chuck 231 by using the first mover 250 of the moving device 256.

Subsequently, the control device 70 performs an imaging processing of imaging the alignment marks M1 and M2 provided on the upper wafer W1 and the lower wafer W2 (process S202).

In the imaging processing, first, the control device 70 controls the adjuster 400 to adjust the depth of focus of the alignment mark imaging device 300, thereby locating the upper wafer W1 and the lower wafer W2 within a depth of focus D of the alignment mark imaging device 300, as shown in FIG. 12. In this state, the control device 70 controls the alignment mark imaging device 300 to image the alignment marks M1 and M2 provided on the upper wafer W1 and the lower wafer W2. As a result, an image focused on both of the alignment marks M1 and M2 is obtained. This image data is output to the control device 70. The control device 70 performs edge detection on the acquired image data to detect the alignment marks M1 and M2.

In this way, in the bonding system 1 according to the present exemplary embodiment, the alignment marks M1 and M2 are imaged by using the alignment mark imaging device 300 with the upper wafer W1 and the lower wafer W2 positioned within the depth of focus D of the alignment mark imaging device 300.

This makes it possible to precisely detect, during the approach processing, the alignment marks M1 and M2 for adjusting the horizontal position of the lower chuck 231 relative to the upper chuck 230 by using the image focused on both of the alignment marks M1 and M2. Therefore, the accuracy of adjustment of the horizontal position of the lower chuck 231 based on the alignment marks M1 and M2 can be improved, and as a result, the bonding accuracy between the substrates can be improved.

In addition, the control device 70 locates the upper wafer W1 and the lower wafer W2 within the depth of focus D of the alignment mark imaging device 300 by reducing the depth of focus D of the alignment mark imaging device 300 with a decrease of the distance between the upper chuck 230 and the lower chuck 231. For example, as shown in FIG. 13, the control device 70 may increase the numerical aperture of the alignment mark imaging device 300 by increasing an aperture width AW of the adjuster 400, thereby reducing the depth of focus D of the alignment mark imaging device 300. This makes it possible to obtain an image in focus on both of the alignment marks M1 and M2 in real time when the upper chuck 230 and the lower chuck 231 are brought closer to each other, so that the alignment marks M1 and M2 can be detected with higher accuracy. Therefore, the accuracy of the adjustment of the horizontal position of the lower chuck 231 based on the detect result of alignment marks M1 and M2 can be improved, and as a result, the bonding accuracy between the substrates can be further bettered.

Thereafter, the control device 70 controls the moving device 256 based on the detection result (imaging result) of the alignment marks M1 and M2 to adjust the horizontal position of the lower chuck 231 relative to the upper chuck 230. Specifically, the control device 70 controls the moving device 256 such that the center position of the ring shape (see FIG. 8) of the alignment mark M2 coincides with the center position of the ring shape (see FIG. 7) of the alignment mark M1, thereby adjusting the horizontal position of the lower chuck 231 relative to the upper chuck 230.

As a result, the horizontal position of the lower chuck 231 can be adjusted with high accuracy based on the highly accurate detection result of the alignment marks M1 and M2, and as a result, the bonding accuracy between the substrates can be improved.

Then, the control device 70 makes a determination on whether the upper chuck 230 and the lower chuck 231 have approached each other within a preset distance (process S204).

If the upper chuck 230 and the lower chuck 231 have not come within the preset distance (No in the process S204), the control device 70 returns back to the process S202, and performs the imaging processing (process S202) and the horizontal position adjustment processing (process S203) again. That is, the control device 70 performs the imaging processing and the horizontal position adjustment processing multiple times during the approach processing.

As a result, the image focused on both of the alignment marks M1 and M2 can be obtained in real time until immediately before the upper wafer W1 and the lower wafer W2 are bonded, so that the alignment marks M1 and M2 can be detected with higher accuracy. Therefore, the accuracy of the adjustment of the horizontal position of the lower chuck 231 based on the detection result of the alignment marks M1 and M2 can be further improved, and as a result, the bonding accuracy between the substrates can be further improved.

When the upper chuck 230 and the lower chuck 231 have come within the preset distance in the process S204 (Yes in the process S204), the control device 70 stops the upper chuck 230 and the lower chuck 231 from approaching each other (process S205). That is, the control device 70 stops the raising of the lower chuck 231 by using the first mover 250 of the moving device 256. In this way, the series of processes of the position alignment processing is completed.

### Modification Examples

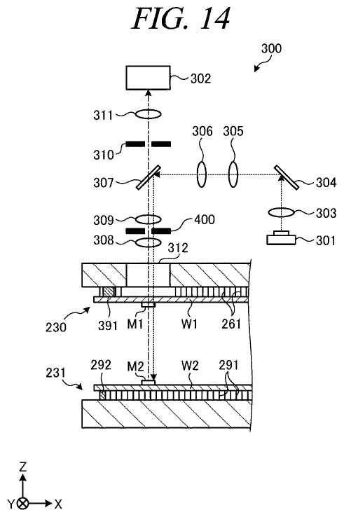

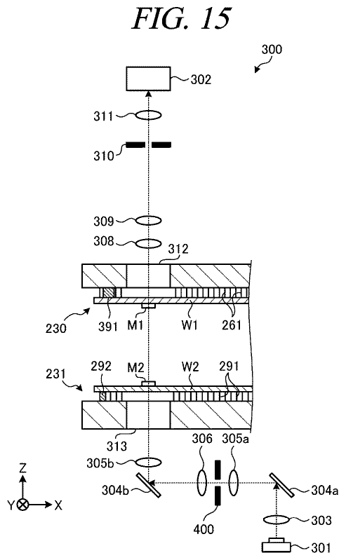

Now, various modification examples of the exemplary embodiment will be described with reference to FIG. 14 and FIG. 15. FIG. 14 is a diagram illustrating a configuration of the alignment mark imaging device 300 according to a first modification example of the exemplary embodiment.

As shown in FIG. 14, in the first modification example, the adjuster 400 is provided between the relay lens 309 and the objective lens 308. With this configuration, the adjuster 400 can reduce the depth of focus of the alignment mark imaging device 300 by increasing the aperture width and thus increasing the numerical aperture, the same as in the exemplary embodiment.

In addition, the adjuster 400 may be provided between the relay lens 309 and the objective lens 308, and, also, between the condensing lens 305 and the collimator lens 306.

FIG. 15 is a diagram illustrating a configuration of the alignment mark imaging device 300 according to a second modification example of the exemplary embodiment.

As shown in FIG. 15, the alignment mark imaging device 300 according to the second modification example includes the light source 301 disposed below the lower chuck 231, and the imager 302 disposed above the upper chuck 230.

Also, the alignment mark imaging device 300 is equipped with the collimator lenses 303 and 306, reflecting mirrors 304a and 304b, and condensing lenses 305a and 305b, which are positioned below the lower chuck 231. The alignment mark imaging device 300 also includes the objective lens 308, the relay lens 309, the imaging aperture 310, and the imaging lens 311, which are positioned above the upper chuck 230. Also, the upper chuck 230 is provided with the through hole 312 that is formed through the upper chuck 230 in the thickness direction, and the lower chuck 231 is provided with a through hole 313 that is formed through the lower chuck 231 in the thickness direction.

The light source 301 emits infrared light. The collimator lens 303 collimates the light emitted from the light source 301. The reflecting mirror 304a changes the path of the light incident vertically upwards from the collimator lens 303 into a horizontal direction, directing the light to the condensing lens 305a. The condensing lens 305a condenses the light incident from the reflecting mirror 304a so that the light is incident on the collimator lens 306. The collimator lens 306 collimates the light incident from the condensing lens 305a, directing it to the reflecting mirror 304b. The reflecting mirror 304b changes the path of the light incident horizontally from the collimator lens 306 into a vertically upward direction, making the light incident on the condensing lens 305b. The condensing lens 305b condenses the light incident from the reflecting mirror 304b toward the through hole 313 side.

The objective lens 308 condenses the light incident from the through hole 312 so that the light is incident on the relay lens 309. The relay lens 309 passes the light incident from the objective lens 308 to the imaging lens 311. The imaging aperture 310 is disposed between the relay lens 309 and the imaging lens 311, and adjusts the amount of the light that is sent from the relay lens 309 to the imaging lens 311. The imaging lens 311 focuses the light incident from the relay lens 309 toward the imager 302.

With this configuration, the light source 301 of the alignment mark imaging device 300 emits the light vertically upwards from below the lower chuck 231. As shown by dashed-line arrows in FIG. 15, the light emitted from the light source 301 reaches the upper wafer W1 and the lower wafer W2 via the collimator lens 303, the reflecting mirror 304a, the condensing lens 305a, the collimator lens 306, the reflecting mirror 304b, the condensing lens 305b, and the through hole 313. Thereafter, the light transmitted through the upper wafer W1 and the lower wafer W2 reaches the imager 302 via the through hole 312, the objective lens 308, the relay lens 309, the imaging aperture 310, and the imaging lens 311. That is, the imager 302 images the alignment marks M1 and M2 by using the transmitted light through the through hole 312.

Further, the adjuster 400 is provided between the condensing lens 305a and the collimator lens 306, the same as in the exemplary embodiment.

Alternatively, the adjuster 400 may be provided between the relay lens 309 and the objective lens 308. Still alternatively, the adjuster 400 may be provided between the relay lens 309 and the objective lens 308, and, also, between the condensing lens 305a and the collimator lens 306.

### Others

The above exemplary embodiment has been described for the example where the first substrate W1 and the second substrate W2 have the circular plate shapes with the substantially same diameter. However, one of the first substrate W1 and the second substrate W2 may have a shape other than the circular plate shape. By way of example, the second substrate W2 may be a rectangular chip of about 30 mm×30 mm obtained by singulating a circular plate-shaped substrate having a diameter of about 300 mm into pieces through a dicing process or the like.

In addition, in the above-described exemplary embodiment, the adjuster 400 adjusts the depth of focus of the alignment mark imaging device by varying the numerical aperture of the alignment mark imaging device 300. However, the depth of focus of the alignment mark imaging device may be adjusted by using a parameter other than the numerical aperture. By way of example, in the bonding system 1, the light source 301 of the alignment mark imaging device 300 may adjust the depth of focus of the alignment mark imaging device 300 by varying the wavelength of the light emitted from the light source 301.

As described above, a bonding apparatus according to the exemplary embodiment (as an example, the bonding apparatus 41) includes a first holder (as an example, the upper chuck 230), a second holder (as an example, the lower chuck 231), a moving device (as an example, the moving device 256), an optical system (as an example, the alignment mark imaging device 300), an adjusting device (for example, the adjuster 400), and a controller (for example, the controller 71). The first holder holds a first substrate (as an example, the upper wafer W1). The second holder holds a second substrate (as an example, the lower wafer W2) to be bonded to the first substrate. The moving device brings one of the first holder and the second holder closer to the other. The optical system radiates the light to the first substrate held by the first holder and the second substrate held by the second holder to image alignment marks (as an example, the alignment marks M1 and M2) provided on the first substrate and the second substrate by reflected light or transmitted light. The adjusting device is provided on an optical path of the optical system and serves to adjust the depth of focus (as an example, the depth of focus D) of the optical system. The controller performs an approach processing and an imaging processing. In the approach processing, the moving device is controlled to bring one of the first holder and the second holder closer to the other. In the imaging processing, the adjusting device is controlled to adjust the depth of focus of the optical system to locate the first substrate and the second substrate within the depth of focus of the optical system during the approach processing, and, then, the alignment marks of the first substrate and the second substrate are imaged by using the optical system.

Therefore, according to the bonding apparatus 41 of the present exemplary embodiment, the bonding accuracy between the substrates can be improved.

It should be noted that the above-described exemplary embodiment is illustrative in all aspects and is not anyway limiting. In fact, the above-described exemplary embodiment can be embodied in various forms. The above-described exemplary embodiment may be omitted, replaced and modified in various ways without departing from the scope and the spirit of claims.

According to the exemplary embodiment, it is possible to improve the bonding accuracy between the substrates.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

We claim:

1. A bonding apparatus, comprising:
a first holder configured to hold a first substrate;
a second holder configured to hold a second substrate to be bonded to the first substrate;
a mover configured to bring a first one of the first holder and the second holder closer to a second one of the first holder and the second holder;
an optical system configured to radiate light to the first substrate held by the first holder and the second substrate held by the second holder to image alignment marks provided on the first substrate and the second substrate by reflected light or transmitted light;
an adjusting device provided on an optical path of the optical system, and configured to adjust a depth of focus of the optical system; and
control circuitry configured to perform:
an approach processing of controlling the mover to bring the first one of the first holder and the second holder closer to the second one of the first holder and the second holder; and
an imaging processing of imaging, during the approach processing, the alignment marks of the first substrate and the second substrate by the optical system, after locating the first substrate and the second substrate within the depth of focus of the optical system by controlling the adjusting device to adjust the depth of focus of the optical system.

2. The bonding apparatus of claim 1,
wherein the adjusting device adjusts the depth of focus of the optical system by varying a numerical aperture of the optical system.

3. The bonding apparatus of claim 1,
wherein, in the imaging processing, the control circuitry locates the first substrate and the second substrate within the depth of focus of the optical system by controlling the adjusting device to reduce the depth of focus of the optical system with a decrease of a distance between the first holder and the second holder.

4. The bonding apparatus of claim 1,
wherein the mover moves the first one of the first holder and the second holder in a horizontal direction to adjust a horizontal position of the second holder with respect to the first holder, and
the control circuitry is further configured to perform, during the approach processing, a horizontal position adjustment processing of controlling, based on an imaging result from the imaging processing, the mover to adjust the horizontal position of the second holder with respect to the first holder.

5. The bonding apparatus of claim 4,
wherein the control circuitry performs the imaging processing and the horizontal position adjustment processing multiple times during the approach processing.

6. The bonding apparatus of claim 1,
wherein the optical system includes multiple optical systems, and
the multiple optical systems are configured to respectively image alignment marks that are provided at multiple positions on the first substrate and the second substrate in one-to-one correspondence with the multiple optical systems.

7. The bonding apparatus of claim 1,
wherein the optical system is configured to be moved in a horizontal direction according to positions of the alignment marks provided on the first substrate and the second substrate.

8. A bonding system, comprising:
a surface modifying apparatus configured to modify surfaces of a first substrate and a second substrate;
a surface hydrophilizing apparatus configured to hydrophilize the modified surfaces of the first substrate and the second substrate; and
a bonding apparatus configured to bond the hydrophilized first and second substrates by an intermolecular force,
wherein the bonding apparatus comprises:
a first holder configured to hold the first substrate;
a second holder configured to hold the second substrate;
a mover configured to bring a first one of the first holder and the second holder closer to a second one of the first holder and the second holder;
an optical system configured to radiate light to the first substrate held by the first holder and the second substrate held by the second holder to image alignment marks provided on the first substrate and the second substrate by reflected light or transmitted light;
an adjusting device provided on an optical path of the optical system, and configured to adjust a depth of focus of the optical system; and
control circuitry configured to perform:
an approach processing of controlling the mover to bring the first one of the first holder and the second holder closer to the second one of the first holder and the second holder; and
an imaging processing of imaging, during the approach processing, the alignment marks of the first substrate and the second substrate by the optical system, after locating the first substrate and the second substrate within the depth of focus of the optical system by controlling the adjusting device to adjust the depth of focus of the optical system.

9. The bonding system of claim 8,
wherein the adjusting device adjusts the depth of focus of the optical system by varying a numerical aperture of the optical system.

10. The bonding system of claim 9,
wherein, in the imaging processing, the control circuitry locates the first substrate and the second substrate within the depth of focus of the optical system by controlling the adjusting device to reduce the depth of focus of the optical system with a decrease of a distance between the first holder and the second holder.

11. The bonding system of claim 8,
wherein the mover moves the first one of the first holder and the second holder in a horizontal direction to adjust a horizontal position of the second holder with respect to the first holder, and
the control circuitry is further configured to perform, during the approach processing, a horizontal position adjustment processing of controlling, based on an imaging result from the imaging processing, the mover to adjust the horizontal position of the second holder with respect to the first holder.

12. The bonding system of claim 11,
wherein the control circuitry performs the imaging processing and the horizontal position adjustment processing multiple times during the approach processing.

13. The bonding system of claim 8,
wherein the optical system includes multiple optical systems, and
the multiple optical systems are configured to respectively image alignment marks that are provided at multiple positions on the first substrate and the second substrate in one-to-one correspondence with the multiple optical systems.

14. The bonding system of claim 8,
wherein the optical system is configured to be moved in a horizontal direction according to positions of the alignment marks provided on the first substrate and the second substrate.

15. A bonding method, comprising:
holding a first substrate by using a first holder configured to hold the first substrate;
holding a second substrate to be bonded to the first substrate, by using a second holder configured to hold the second substrate;
bringing a first one of the first holder and the second holder closer to a second one of the first holder and the second holder by using a mover configured to bring the first one of the first holder and the second holder closer to the second one of the first holder and the second holder; and
imaging, during the bringing of the first one of the first holder and the second holder closer to the second one of the first holder and the second holder, alignment marks of the first substrate and the second substrate by using an optical system configured to radiate light to the first substrate and the second substrate to image the alignment marks provided on the first substrate and the second substrate by reflected light or transmitted light, after locating the first substrate and the second substrate within a depth of focus of the optical system by adjusting the depth of focus of the optical system.

16. The bonding method of claim 15, further comprising adjusting the depth of focus of the optical system by varying a numerical aperture of the optical system.

17. The bonding method of claim 15, further comprising in the imaging, locating the first substrate and the second substrate within the depth of focus of the optical system by controlling the adjusting device to reduce the depth of focus of the optical system with a decrease of a distance between the first holder and the second holder.

18. The bonding method of claim 15, further comprising:
moving the first one of the first holder and the second holder in a horizontal direction to adjust a horizontal position of the second holder with respect to the first holder; and
adjusting, based on an imaging result from the imaging, the horizontal position of the second holder with respect to the first holder.

19. The bonding method of claim 15,
wherein the optical system includes multiple optical systems, and
the method further comprises, by the multiple optical systems, imaging alignment marks that are provided at multiple positions on the first substrate and the second substrate in one-to-one correspondence with the multiple optical systems.

20. The bonding method of claim 15, further comprising moving the optical system in a horizontal direction according to positions of the alignment marks provided on the first substrate and the second substrate.
